(19) United States
(12) Patent Application Publication
(10) Pub. No.: US 2026/0006861 A1
(43) Pub. Date: Jan. 1, 2026

(54) CAPPING LAYER FOR TRANSITION METAL DICHALCOGENIDE BASED TRANSISTOR STRUCTURES

(71) Applicant: Intel Corporation, Santa Clara, CA (US)

(72) Inventors: Arnab Sen Gupta, Hillsboro, OR (US); Sarah Atanasov, Beaverton, OR (US); Uygar E. Avci, Portland, OR (US); Pratyush Buragohain, Portland, OR (US); Jiun-Ruey Chen, Hillsboro, OR (US); Mahmut Sami Kavrik, Hillsboro, OR (US); Ande Kitamura, Portland, OR (US); Chia-Ching Lin, Portland, OR (US); Kirby Maxey, Hillsboro, OR (US); Matthew Metz, Portland, OR (US); Carl H. Naylor, Portland, OR (US); Kevin P. O’Brien, Portland, OR (US)

(73) Assignee: Intel Corporation, Santa Clara, CA (US)

(21) Appl. No.: 18/759,040

(22) Filed: Jun. 28, 2024

(51) Int. Cl. H01L 29/76; H01L 21/02; H01L 29/06; H01L 29/24; H01L 29/423; H01L 29/66; H01L 29/775; H01L 29/786

(52) U.S. Cl. CPC H10D 48/362; H01L 21/02568; H01L 21/02603; H10D 30/43; H10D 30/6735; H10D 30/6757; H10D 62/121; H10D 62/80; H10D 99/00

(57) ABSTRACT

Devices, transistor structures, systems, and techniques are described herein related to field effect transistors having one or more metal chalcogenide nanoribbons coupled to a source and a drain. Channel regions of the metal chalcogenide nanoribbons are coupled to a gate structure between the source and the drain. The metal chalcogenide nanoribbons are capped with a layer including an oxide of a metal or metalloid element, optionally doped with or including carbon.

### BACKGROUND

Higher performance, lower cost, increased miniaturization, and greater density of integrated circuits (ICs) are ongoing goals of the electronics industry. To maintain the pace of increasing transistor density, for example, device dimensions must continue to shrink. 2D materials such as transition metal dichalcogenides (TMDs) have the potential to achieve advanced scaling of transistors such as gate-all-around (GAA) or nanoribbon transistors. However, difficulties in the deployment of 2D materials remain, including maintaining the quality and performance of the materials through the process flow needed to complete fabrication of the transistor device structures. It is with respect to these and other considerations that the present improvements have been needed. Such improvements may become critical as the desire to deploy 2D materials in transistor structures becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a cross-sectional side view of a transistor structure having capping layers on metal chalcogen layers of the transistor structure;

FIG. 2 illustrates a cross-sectional side view of a transistor structure having capping layers that extend across an entire top surface of metal chalcogen layers of the transistor structure;

FIG. 3 illustrates a cross-sectional side view of a transistor structure having capping layers on metal chalcogen layers of the transistor structure such that the metal chalcogen layers are directly on a gate dielectric of the transistor structure;

FIG. 4 illustrates a cross-sectional side view of a planar back-gated transistor structure having a capping layer on a metal chalcogen layer of the planar back-gated transistor structure;

FIG. 5 illustrates a cross-sectional side view of a planar dual-gate transistor structure having a capping layer on a metal chalcogen layer of the planar dual-gate transistor structure;

FIG. 6 is a flow diagram illustrating methods for forming transistor structures having one or more capping layers on one or more corresponding metal chalcogen layers of the transistor structures;

FIGS. 7, 8, 9, 10, 11, 12, 13, 14, 15, 16, 17, and 18 are cross-sectional views of transistor structures having one or more capping layers on one or more corresponding metal chalcogen layers of the transistor structures evolving as the methods of FIG. 6 are practiced;

FIG. 19 illustrates exemplary systems employing metal chalcogen material-based transistor structures having a capping layer on the metal chalcogen nanoribbons; and

FIG. 20 is a functional block diagram of an electronic computing device, all in accordance with some embodiments.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Devices, transistor structures, integrated circuit dies, apparatuses, systems, and techniques are described herein related to a capping layer on a transition metal dichalcogenide or similar channel material. The capping layer protects the channel material during device fabrication for improved device performance and reliability.

As discussed, transition metal dichalcogenide (TMD) materials or similar materials, which may be referred to as 2D materials, may be deployed as the semiconductor in a transistor structure such as a gate-all-around (GAA), dual gate, nanoribbon, or even planar single channel transistors. In some embodiments, 2D material layers may be deployed as a stack of separated nanoribbons in a transistor. Current difficulties in the deployment of 2D materials include material reliability due to the 2D materials relative sensitivity to fabrication processing needed to complete the transistor device structures. For example, it is undesirable for the 2D materials to oxidize during device fabrication due to the oxidization degrading the properties of the 2D materials.

The techniques and structures discussed herein provide for a capping layer on the 2D channel material to protect the 2D channel material during subsequent processing. The capping layer is applied directly on the 2D channel material and may include any material layer that protects the 2D channel material from subsequent fabrication processes such as lithography, etch, anneal, and others. In some embodiments, the capping layer is an oxide such as HfOₓ (where x is 2 or approximately 2, such as in the range of 1.9 to 2.1), SiOₓ (where x is 2 or approximately 2, such as in the range of 1.9 to 2.1), ZrOₓ (where x is 2 or approximately 2, such as in the range of 1.9 to 2.1), YₓO_{z} (where x is 2 or approximately 2, such as in the range of 1.9 to 2.1 and z is 3 or approximately 3, such as in the range of 2.9 to 3.1), AlₓO_{z} (where x is 2 or approximately 2, such as in the range of 1.9 to 2.1 and z is 3 or approximately 3, such as in the range of 2.9 to 3.1), TaₓO_{z} (where x is 2 or approximately 2, such as in the range of 1.9 to 2.1 and z is 5 or approximately 5, such as in the range of 4.9 to 5.1), NbO, NbOₓ (where x is 2 or approximately 2, such as in the range of 1.9 to 2.1), NbₓO_{z} (where x is 2 or approximately 2, such as in the range of 1.9 to 2.1 and z is 5 or approximately 5, such as in the range of 4.9 to 5.1), or TiOₓ where x is 2 or approximately 2, such as in the range of 1.9 to 2.1). For example, the capping layer may be one of HfO₂, SiO₂, ZrO₂, Y₂O₃, Al₂O₃, Ta₂O₅, NbO, NbO₂, Nb₂O₅, or TiO₂. In other embodiments, the capping layer may be a non-stoichiometric oxide of the discussed metal or metalloid element. In some embodiments, the capping layer includes carbon such that capping layer includes a carbon layer and the oxide on the carbon layer, a carbon doped oxide, or a compound of a metal or metalloid element, carbon, and oxygen. For example, the capping layer may be one of C+HfOx, C+SiOx, C+ZrOx, C+YOx, C+AlOx, C+TaOx, C+NbOx, or C+TiOx (e.g., a carbon doped oxide of any of those listed above). In some embodiments, the incorporation of carbon provides for oxygen scavenging or gettering to further protect the 2D channel material. Additional details of the capping layer are discussed herein below.

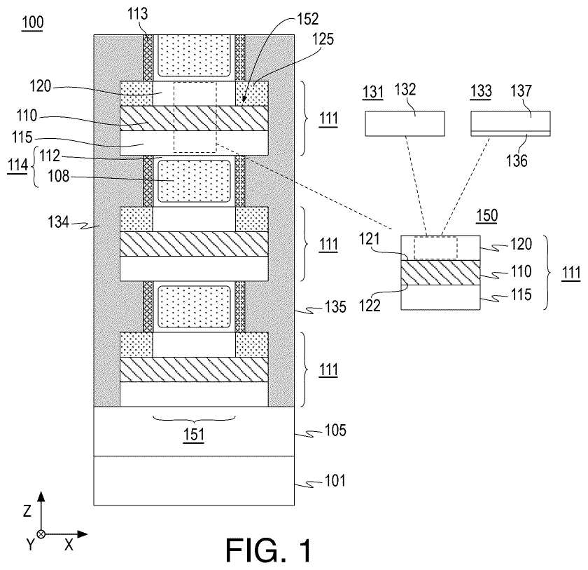

FIG. 1 illustrates a cross-sectional side view of a transistor structure 100 having capping layers 120 on metal chalcogen layers 110 of transistor structure 100, arranged in accordance with at least some implementations of the present disclosure. For example, a GAA transistor, dual gate transistor, or nanoribbon transistor includes a stack of nanoribbons such as metal chalcogen layers 110 that extend from a source structure 134 to a drain structure 135. Although illustrated with three nanoribbons or channel structures, transistor structure 100 may include any number of nanoribbons or channel structures such as two, four, five, or more. Although discussed with respect to metal chalcogen layers 110, the layers of transistor structure 100 may be any suitable 2D material. Such layers may be characterized as channel structures, material layers, semiconductor layers, nanoribbons, or the like. For example, although discussed with respect to metal chalcogen layers 110 such that metal chalcogen layers 110 include a metal and a chalcogen, layers 110 may be any suitable material such as a 2D material.

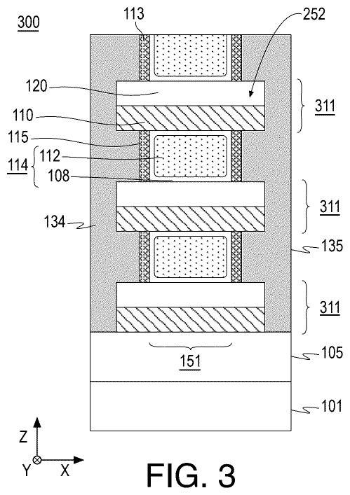

As shown, each of metal chalcogen layers 110 may be part of a material stack 111 that includes metal chalcogen layers 110, capping layers 120, and optional material layers 115. In the embodiment of FIG. 1, metal chalcogen layers 110 are sandwiched between material layers 115 and capping layers 120 such that each material layer 115 is directly on a respective metal chalcogen layer 110 and each capping layer 120 is directly on a respective metal chalcogen layer 110 with capping layer 120 being opposite metal chalcogen layer 110 from material layer 115. For example, material layers 115 may each be an oxide of a metal or metalloid element. In some embodiments, material layers 115 are hafnium oxide (i.e., include a compound of hafnium and oxygen), which may aid in the growth of metal chalcogen layers 110. In some embodiments, material layers 115 are silicon oxide (i.e., include a compound of silicon and oxygen). Material layers 115 may each be the same material, or they may be different. In some embodiments, material layers 115 are not present, as discussed further herein below with respect to FIG. 3.

In some embodiments, one or more of metal chalcogen layers 110 includes a transition metal and a chalcogen. The transition metal may be any transition metal such as any element of groups 4 through 11, the group 3 elements scandium and yttrium, and the inner transition metals (e.g., f-block lanthanide and actinide series). The chalcogen may be any chalcogen such as group 16 elements, excluding oxygen. Notably advantageous transition metals are molybdenum and tungsten. Notably advantageous chalcogens are sulfur, selenium, and tellurium. In some embodiments, one or more of metal chalcogen layers 110 are stoichiometric TMDs. For example, one or more of metal chalcogen layers 110 may be MoS₂, WS₂, MoSe₂, WSe₂, MoTe₂, or WTe₂. Notably advantageous TMDs are WSe₂, WS₂, MoSe₂, and MoS₂. For example, metal chalcogen layers 110 may be a material layer including a transition metal (i.e., any of Mo, W, Zr, Nb, Ta, Ti, Ni, Ga, In, or Bi) and a chalcogen (i.e., any of S, Se, or Te). In some embodiments, metal chalcogen layers 110 are one or more of MoS₂, WS₂, MoSe₂, WSe₂, MoTe₂, or WTe₂. ZrS₂, SrSe₂, NbSe₂, NbS₂, TaS₂, TiS₂, NiSe₂, GaSe, GaTe, InSe, Bi₂Se₃, and others, with the above discussed advantageous TMDs having benefits of material properties, workability, and others. Metal chalcogen layers 110 may have any suitable thicknesses. In some embodiments, metal chalcogen layers 110 each have a thickness of not more than 1 nm. In some embodiments, metal chalcogen layers 110 each have a thickness of about 0.33 nm.

Each of metal chalcogen layers 110 extend between and are coupled to source structure 134 and drain structure 135. In some embodiments, one or more of metal chalcogen layers 110 is a molecular monolayer (e.g., a monolayer of a transition metal and a chalcogen). In some embodiments, the molecular monolayer includes an atomic center transition metal layer and atomic chalcogen layers on both sides of the atomic center transition metal layer. In some embodiments, the molecular monolayer has a thickness of about 0.33 nm. In some embodiments, metal chalcogen layers 110 are n-type such as MoS₂ or WS₂. In some embodiments, metal chalcogen layers 110 are p-type such as MoSe₂ or WSe₂. In various embodiments, transistor structure 100 is an n-type metal oxide semiconductor (NMOS) device or a p-type metal oxide semiconductor (PMOS) device. In some embodiments, an NMOS device and a PMOS device may be integrated in an integrated circuit (IC) device or die.

As shown, in a channel region 151 of each of metal chalcogen layers 110, control of transistor structure 100 is provided by a gate structure 114 that includes a gate electrode 108 separated from metal chalcogen layers 110 by a gate dielectric 112. A channel region indicates a region of each of metal chalcogen layers 110 adjacent to and controlled by gate structure 114 to switch transistor structure 100 in operation. The term channel region indicates a region of a material layer adjacent to a gate dielectric and gate electrode that is to be controlled by the gate electrode to switch the transistor structure in operation; notably, a region of a material layer need not be in operation to be characterized as a channel region, channel material, or the like. Metal chalcogen layers 110 also include source and drain contact regions and a spacer region that are outside of channel region 151 and are adjacent to spacer material 113 or adjacent to and coupled to source structure 134 and drain structure 135.

Also as shown, in some embodiments, capping layers 120 are recessed such that a region 152 of metal chalcogen layers 110 are covered by a material 125 that may be a conductor to provide additional contact area with metal chalcogen layers 110. In some embodiments, material 125 is a part of source structure 134 and drain structure 135 such that additional contact area with metal chalcogen layers 110 to reduce contact resistance. For example, material 125 may be the same material and may be continuous with source structure 134 and drain structure 135. In some embodiments, as discussed herein, material 125 is absent and capping layer 120 extends across an entire top surface of metal chalcogen layers 110.

As shown in insert 150, each material stack 111 includes capping layer 120 directly on a top side 121 (or top surface) of metal chalcogen layers 110. For example, capping layer 120 may be directly on metal chalcogen layer 110 at least in channel regions 151. Optional material layer 115 is directly on a bottom side 122 (or bottom surface) of metal chalcogen layer 110. As used herein, top and bottom or similar terms are used in accordance with the buildup direction (i.e., the positive z-direction) of transistor structures in accordance with their accepted use in the art. Capping layer 120 advantageously provides protection for metal chalcogen layers 110 during subsequent processing such as lithography, etch, anneal and others. Thereby, transistor structure 100 includes one or more metal chalcogen layers 110 (e.g., a material layer including a transition metal and a chalcogen) extending between and coupled to each of source structure 134 and drain structure 135, one or more capping layers 120 (e.g., a material layer including a compound of a metal or metalloid element, oxygen, and optionally carbon) directly on metal chalcogen layers 110, and gate structure 114 adjacent to channel region 151 of metal chalcogen layers 110, such that gate structure 114 includes gate electrode 108 (e.g., a gate metal) separated from channel region 151 by gate dielectric 112 (e.g., a gate dielectric material).

As discussed, capping layers 120 protect metal chalcogen layers 110, and capping layers 120 may be any suitable material or materials in any suitable configuration that provides such protection for metal chalcogen layers 110. As with metal chalcogen layers 110, capping layers 120 may be the same materials or they may be different. As shown with respect to insert 131, in some embodiments, one or more of capping layers 120 are a substantially monolithic material layer 132 such that material layer 132 is a material compound having substantially similar qualities across its depth (i.e., in the z-direction).

In some embodiments, one or more of capping layers 120 is an oxide of a metal or metalloid element. The metal or metalloid element may be one of hafnium, silicon, zirconium, yttrium, aluminum, tantalum, niobium, or titanium. Such material layers 132 protect metal chalcogen layers 110 inclusive of protection from surface oxidation, surface damage (i.e., due to lithography and/or etch), and others. In some embodiments, one or more of capping layers 120 is hafnium oxide (e.g., a compound including hafnium and oxygen). In some embodiments, one or more of capping layers 120 is silicon oxide (e.g., a compound including silicon and oxygen). In some embodiments, one or more of capping layers 120 is zirconium oxide (e.g., a compound including zirconium and oxygen. In some embodiments, one or more of capping layers 120 is yttrium oxide (e.g., a compound including yttrium and oxygen). In some embodiments, one or more of capping layers 120 is aluminum oxide (e.g., a compound including aluminum and oxygen). In some embodiments, one or more of capping layers 120 is tantalum oxide (e.g., a compound including tantalum and oxygen). In some embodiments, one or more of capping layers 120 is niobium oxide (e.g., a compound including niobium and oxygen. In some embodiments, one or more of capping layers 120 is titanium oxide (e.g., a compound including titanium and oxygen). Such materials and example stoichiometries are discussed herein above. A notably advantageous metal or metalloid oxide is aluminum oxide. Such material layers may be stoichiometric or non-stoichiometric. Stoichiometric materials have substantially common stoichiometry while non-stoichiometric metal or metalloid oxides are materials that deviate from common stoichiometry. As discussed, each of capping layers 120 may be the same materials such that each is the discussed material, or they may be different.

In some embodiments, one or more of capping layers 120 is oxide of a metal or metalloid clement that is doped with carbon or includes carbon. The metal or metalloid element may be one of hafnium, silicon, zirconium, yttrium, aluminum, tantalum, niobium, or titanium. Such material layers 132 again protect metal chalcogen layers 110 inclusive of protection from surface oxidation, surface damage (i.e., due to lithography and/or etch), and others. In addition, the inclusion of carbon can provide for gettering or scavenging of oxygen to further reduce or eliminate surface oxidation during fabrication processing. In some embodiments, one or more of capping layers 120 is a hafnium oxide material doped with or including carbon (e.g., a compound including hafnium, oxygen, and carbon, C+HfOₓ). In some embodiments, one or more of capping layers 120 is a silicon oxide material doped with or including carbon (e.g., a compound including silicon, oxygen, and carbon, C+SiOₓ). In some embodiments, one or more of capping layers 120 is zirconium oxide material doped with or including carbon (e.g., a compound including zirconium, oxygen, and carbon, C+ZrOₓ). In some embodiments, one or more of capping layers 120 is an yttrium oxide material doped with or including carbon (e.g., a compound including yttrium, oxygen, and carbon, C+YₓO_{z}). In some embodiments, one or more of capping layers 120 is an aluminum oxide material doped with or including carbon (e.g., a compound including aluminum, oxygen, and carbon, C+AlOₓ). In some embodiments, one or more of capping layers 120 is a tantalum oxide material doped with or including carbon (e.g., a compound including tantalum, oxygen, and carbon, C+TaOₓ). In some embodiments, one or more of capping layers 120 is a niobium oxide material doped with or including carbon (e.g., a compound including niobium, oxygen, and carbon, C+NbOₓ). In some embodiments, one or more of capping layers 120 is a titanium oxide material doped with or including carbon (e.g., a compound including titanium, oxygen, and carbon, C+TiOₓ). Notably advantageous metal or metalloid oxides doped with or including carbon are C+HfOₓ, C+SiOₓ, C+ZrOₓ, C+YOₓ, and C+AlOₓ.

Such material layers may include any suitable amount of carbon. In some embodiments, one or more of capping layers 120 includes not less than 0.1% carbon. In some embodiments, one or more of capping layers 120 includes not less than 1% carbon. In some embodiments, one or more of capping layers 120 includes not less than 2% carbon. In some embodiments, one or more of capping layers 120 includes not less than 5% carbon. In some embodiments, one or more of capping layers 120 includes not less than 0.1% carbon and not more than 10% carbon. Other atomic percentages of carbon can be used.

Capping layers 120 (i.e., material layer 132) may have any suitable thicknesses. As discussed, metal chalcogen layers 110 may each have a thickness of not more than 1 nm. Similarly, capping layers 120 may have a thickness at the nm scale. In some embodiments, capping layers 120 each have a thickness of not more than 10 nm. In some embodiments, capping layers 120 each have a thickness of not more than 5 nm. In some embodiments, capping layers 120 each have a thickness of not less than 1 nm and not more than 5 nm. Other thicknesses may be used. Furthermore, capping layers 120 may have any suitable morphology. In some embodiments, capping layers 120 are crystalline or nanocrystalline materials. As used herein the term crystalline indicates a material whose constituents are arranged in a highly ordered microscopic structure forming a crystal lattice and a nanocrystalline material has nanocrystals having at least one dimension smaller than 100 nm.

In some embodiments, capping layers 120 include a multilayer stack of materials, as shown with respect to insert 133, such that one or more of capping layers 120 include a carbon layer 136 directly on metal chalcogen layer 110 and a material layer 137 directly on carbon layer 136 such that material layer 137 is a compound of an oxide of a metal or metalloid element. The metal or metalloid element may be one of hafnium, silicon, zirconium, yttrium, aluminum, tantalum, niobium, or titanium. Material layer 137 may be any oxide material discussed with respect to material layers 132 (i.e., HfOₓ, SiOₓ, ZrOₓ, YₓO_{z}, AlOₓ, TaOₓ, NbOₓ, or TiOₓ). A notably advantageous carbon layer 136 and material layer 137 combination is an aluminum oxide layer on a carbon layer.

Carbon layer 136 and material layer 137 may have any suitable thicknesses. In some embodiments, carbon layer 136 has a thickness of about 1 nm. In some embodiments, carbon layer 136 has a thickness of not less than 1 nm. In some embodiments, carbon layer 136 has a thickness of about 2 nm. In some embodiments, carbon layer 136 has a thickness of not less than 0.5 nm and not more than about 2 nm. Material layer 137 may have any thickness discussed with respect to material layer 132. In some embodiments, material layer 137 has a thickness of not more than 5 nm. In some embodiments, material layer 137 has a thickness of not less than 1 nm and not more than 5 nm. Other thicknesses may be used. Furthermore, carbon layer 136 and material layer 137 may be crystalline or nanocrystalline in some embodiments.

In some embodiments, metal chalcogen layers 110 are free of dopant materials in channel region 151 while being doped outside of channel region 151 for reduced contact resistance. In some embodiments, one or both of capping layers 120 and material layers 115 are recessed to increase contact area between source structure 134 and metal chalcogen layers 110 and between drain structure 135 and metal chalcogen layers 110. However such recessing may not be deployed in some embodiments.

With continued reference to FIG. 1, transistor structure 100 includes a substrate 101 and an optional dielectric layer 105. Substrate 101 may include any suitable material or materials. For example, substrate 101 may be a substrate substantially aligned along a predetermined crystal orientation (e.g., <100>, <111>, <110>, or the like). In some embodiments, substrate 101 is a semiconductor material such as monocrystalline silicon (Si), germanium (Ge), silicon germanium (SiGe), a III-V materials-based material (e.g., gallium arsenide (GaAs)), a silicon carbide (SiC), a sapphire (Al₂O₃), or any combination thereof. In some embodiments, substrate 101 is silicon having a <111>crystal orientation. In various embodiments, substrate 101 may include metallization interconnect layers for integrated circuits or electronic devices such as transistors, memories, capacitors, resistors, optoelectronic devices, switches, or any other active or passive electronic devices separated by an electrically insulating layer, for example, an interlayer dielectric, a trench insulation layer, or the like. Optional dielectric layer 105 may act as an etch stop and may include any suitable material such as silicon oxide, silicon nitride, or silicon carbide. Transistor structure 100 may further includes a gate contact, a source contact, and a drain contact, as discussed further herein below.

Transistor structure 100 further includes source structure 134 and drain structure 135, which may be or include a source contact metal and a drain contact metal (e.g., as a liner metal as shown herein below) and a fill metal, or just a single metal material (as shown in FIG. 1). Source structure 134 and drain structure 135 may include any suitable conductive material or materials. Exemplary liner materials (e.g., in direct contact with metal chalcogen layers 110) include antimony, ruthenium, titanium, titanium nitride, or others. Exemplary fill metals include cobalt, tungsten, copper, ruthenium, or others. Source structure 134 and drain structure 135 are separated from gate structure 114 by spacer material 113. Spacer material 113 may include any suitable insulative material or materials such as low k dielectric material. In the example of FIG. 1, spacer material 113 may be on directly on material layer 115 and material 125.

As discussed, transistor structure 100 includes a stack of metal chalcogen layers 110 (e.g., first material layers or nanoribbons) such that one or more of metal chalcogen layers 110 includes a transition metal and a chalcogen. Each of metal chalcogen layers 110 has channel region 151 and source or drain contact regions and/or spacer region outside of channel region 151. Transistor structure 100 also includes gate structure 114, source structure 134, and drain structure 135 coupled to each of metal chalcogen layers 110. Capping layers 120 are directly on metal chalcogen layers 110 and include an oxide of a metal or metalloid element, or an oxide of a metal or metalloid element doped with or including carbon. Capping layers 120 protect metal chalcogen layers 110 for improved device performance.

As discussed, in some embodiments, capping layers 120 are recessed from regions 152 of metal chalcogen layers 110. In other embodiments, capping layers 120 extend across an entire upper surface of metal chalcogen layers 110.

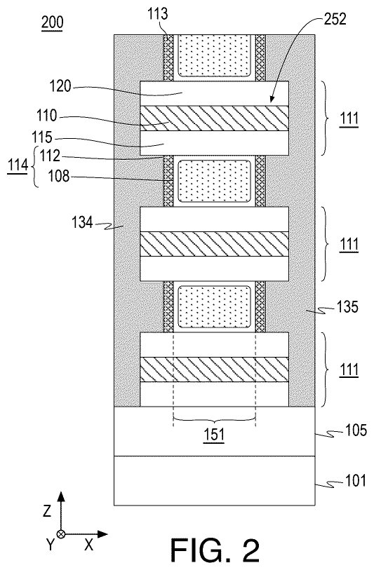

FIG. 2 illustrates a cross-sectional side view of a transistor structure 200 having capping layers 120 that extend across an entire top surface 252 of metal chalcogen layers 110 of transistor structure 200, arranged in accordance with at least some implementations of the present disclosure. In the context of FIG. 2 and elsewhere herein, like components may have any features or characteristics as discussed elsewhere. As shown, in some embodiments, capping layers 120 extend across an entire top surface 252 of each of metal chalcogen layers 110. Such embodiments may offer the advantages of protection of the entirety of entire top surface 252 of metal chalcogen layers 110 and processing simplicity due to the elimination of a recess etch operation, at the cost of decreased source and drain contact area with metal chalcogen layers 110.

In other aspects, transistor structure 200 may have the same features and characteristics discussed with respect to other transistor structures discussed herein. For example, transistor structure 200 includes metal chalcogen layers 110 (i.e., material layers or nanoribbons) extending between and coupled to each of source structure 134 and drain structure 135. Metal chalcogen layers 110 may include any transition metals and chalcogens discussed herein. Capping layers 120 (i.e., material layers) are directly on metal chalcogen layers 110 and include oxygen and a metal or metalloid element (i.e., a compound of a metal or metalloid element) and, optionally, carbon (i.e., a compound of a metal or metalloid element, oxygen, and carbon; a compound of a metal or metalloid element and oxygen on a carbon layer). Gate structure 114 is adjacent to channel region 151 of the metal chalcogen layers 110 and includes gate electrode 108 (i.e., a gate metal) separated from channel region 151 by gate dielectric 112 (i.e., a gate dielectric material).

As discussed, in some embodiments, optional material layers 115 may not be deployed.

FIG. 3 illustrates a cross-sectional side view of a transistor structure 300 having capping layers 120 on metal chalcogen layers 110 of transistor structure 300 such that metal chalcogen layers 110 are directly on gate dielectric 112 of transistor structure 300, arranged in accordance with at least some implementations of the present disclosure. In the example of FIG. 3, capping layers 120 extend across an entire top surface 252 of metal chalcogen layers 110. However, capping layers 120 may be recessed to expose regions 152 (refer to FIG. 1) of metal chalcogen layers 110 in some embodiments. Also as shown, transistor structure 300 may be absent material layers 115 such that metal chalcogen layers 110 are directly on gate dielectric 112. For example, capping layers 120 are directly on metal chalcogen layers 110 to provide material stacks 311. Such embodiments may offer the advantages of increased contact area between metal chalcogen layers 110 and source structure 134 and between metal chalcogen layers 110 and drain structure 135.

In other aspects, transistor structure 300 may have the same features and characteristics discussed with respect to other transistor structures discussed herein. For example, transistor structure 300 includes metal chalcogen layers 110 (i.e., material layers or nanoribbons) extending between and coupled to each of source structure 134 and drain structure 135. Metal chalcogen layers 110 may include any transition metals and chalcogens discussed herein. Capping layers 120 (i.e., material layers) are directly on metal chalcogen layers 110 and include oxygen and a metal or metalloid element (i.e., a compound of a metal or metalloid element) and, optionally, carbon (i.e., a compound of a metal or metalloid element, oxygen, and carbon; a compound of a metal or metalloid element and oxygen on a carbon layer). Gate structure 114 is adjacent to channel region 151 of the metal chalcogen layers 110 and includes gate electrode 108 (i.e., a gate metal) separated from channel region 151 by gate dielectric 112 (i.e., a gate dielectric material). Gate dielectric 112 is directly on metal chalcogen layers 110 in channel region 151 and gate dielectric 112 is directly on capping layers 120 in channel region 151.

Although discussed herein with respect to GAA transistor structures, capping layers 120 may be deployed in planar transistor structures including a single metal chalcogen layer 110.

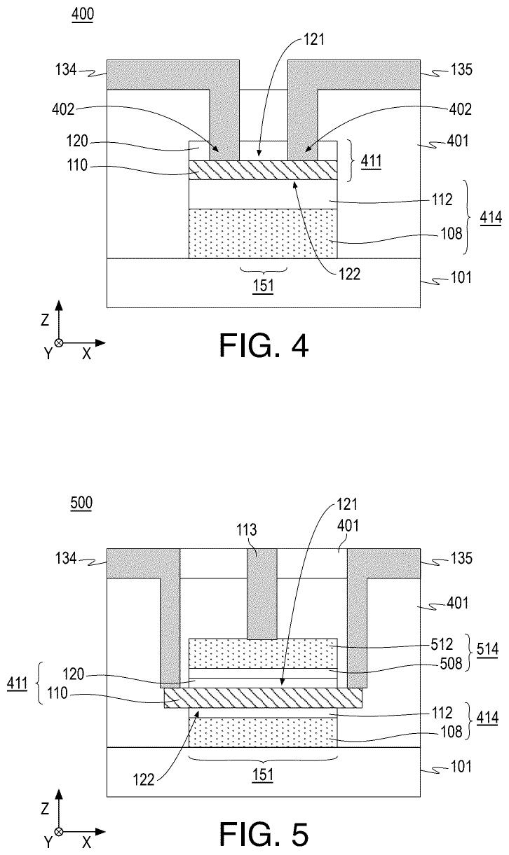

FIG. 4 illustrates a cross-sectional side view of a planar back-gated transistor structure 400 having capping layer 120 on metal chalcogen layer 110 of planar back-gated transistor structure 400, arranged in accordance with at least some implementations of the present disclosure. In the example of FIG. 4, capping layer 120 is on top side 121 of metal chalcogen layer 110 to provide a material stack 411. Furthermore, source structure 134 and drain structure 135 contact metal chalcogen layer 110 on top side 121 and through openings 402 in capping layer 120. Gate structure 414 (i.e., a back-gate structure) includes gate dielectric 112 directly on bottom side 122 of metal chalcogen layer 110 and opposite metal chalcogen layer 110 with respect to capping layer 120. Gate electrode 108 is separated from metal chalcogen layer 110 by gate dielectric 112. Material stack 411, gate structure 414, and at least portions of source structure 134 and drain structure 135 are embedded in dielectric material 401, which may be any suitable insulative material such as silicon oxide, silicon nitride, silicon oxynitride, or the like.

The components of transistor structure 400 may have the same features and characteristics discussed with respect to other transistor structures discussed herein. For example, transistor structure 400 includes a single metal chalcogen layers 110 (i.e., a single nanoribbon) coupled to each of source structure 134 and drain structure 135. Metal chalcogen layer 110 may include any transition metals and chalcogens discussed herein. Capping layer 120 (i.e., material layer) is directly on metal chalcogen layers 110 and includes oxygen and a metal or metalloid clement (i.e., a compound of a metal or metalloid element) and, optionally, carbon (i.e., a compound of a metal or metalloid element, oxygen, and carbon; a compound of a metal or metalloid element and oxygen on a carbon layer). Gate structure 414 is adjacent to channel region 151 of the metal chalcogen layers 110 and includes gate electrode 108 (i.e., a gate metal) separated from channel region 151 by gate dielectric 112 (i.e., a gate dielectric material). Notably advantageous gate electrode 108, gate dielectric 112, and capping layer 120 materials include titanium nitride (TiN), silicon oxide (SiO₂), and aluminum oxide (Al₂O₃), respectively.

FIG. 5 illustrates a cross-sectional side view of a planar dual-gate transistor structure 500 having capping layer 120 on metal chalcogen layer 110 of planar dual-gate transistor structure 500, arranged in accordance with at least some implementations of the present disclosure. In the example of FIG. 5, capping layer 120 is on top side 121 of metal chalcogen layer 110 to provide a material stack 411. Capping layer 120 is recessed from metal chalcogen layer 110 to provide a contact location for source structure 134 and drain structure 135. Source structure 134 and drain structure 135 contact metal chalcogen layer 110 on top side 121.

Gate structure 514 (i.e., a front-gate structure) includes gate dielectric 512 directly on capping layer 120 and opposite metal chalcogen layer 110 with respect to gate dielectric 112. Gate dielectric 512 may have any features, materials, or properties discussed with respect to gate dielectric 512. Gate electrode 508 of gate structure 514 is separated from metal chalcogen layer 110 by gate dielectric 512 (and by capping layer 120). Gate electrode 508 may have any features, materials, or properties discussed with respect to gate electrode 108. Planar dual-gate transistor structure 500 further includes gate structure 414 (i.e., a back-gate structure) includes gate dielectric 112 directly on metal chalcogen layer 110 and opposite metal chalcogen layer 110 with respect to capping layer 120. Gate electrode 108 of gate structure 414 is separated from metal chalcogen layer 110 by gate dielectric 112 of gate structure 414. Material stack 411, gate structure 414, gate structure 514, and at least portions of source structure 134 and drain structure 135 are embedded in dielectric material 401. Although illustrated with respect to a planar dual-gate transistor structure, in some embodiments, a planar transistor may include only gate structure 514 and may be absent gate structure 414.

The components of transistor structure 500 may have the same features and characteristics discussed with respect to other transistor structures discussed herein. For example, transistor structure 500 includes a single metal chalcogen layers 110 (i.e., a single nanoribbon) coupled to each of source structure 134 and drain structure 135. Metal chalcogen layer 110 may include any transition metals and chalcogens discussed herein. Capping layer 120 (i.e., material layer) is directly on metal chalcogen layers 110 and includes oxygen and a metal or metalloid clement (i.e., a compound of a metal or metalloid clement) and, optionally, carbon (i.e., a compound of a metal or metalloid element, oxygen, and carbon; a compound of a metal or metalloid element and oxygen on a carbon layer). Gate structure 414 is adjacent to channel region 151 of the metal chalcogen layers 110 and includes gate electrode 108 (i.e., a gate metal) separated from channel region 151 by gate dielectric 112 (i.e., a gate dielectric material). Gate structure 514 is adjacent to channel region 151 of the metal chalcogen layers 110 and includes gate electrode 508 (i.e., a gate metal) separated from channel region 151 by gate dielectric 512 (i.e., a gate dielectric material). Notably advantageous gate electrode 108, 508, gate dielectric 112, 512, and capping layer 120 materials include titanium nitride (TiN), silicon oxide (SiO₂), and aluminum oxide (Al₂O₃), respectively.

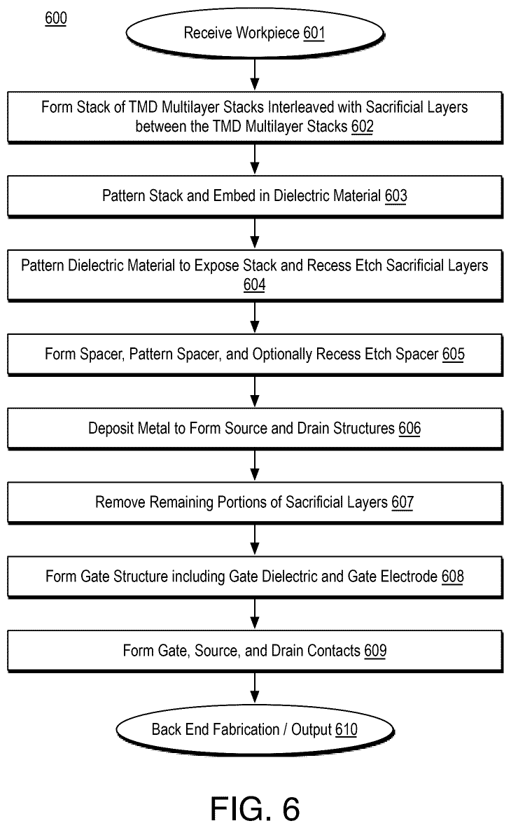

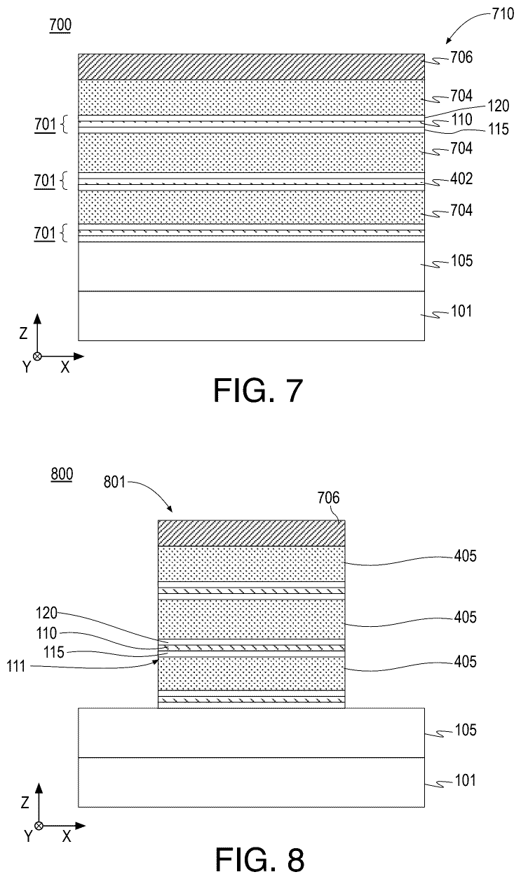

FIG. 6 is a flow diagram illustrating methods 600 for forming transistor structures having one or more capping layers on one or more corresponding metal chalcogen layers of the transistor structures, arranged in accordance with some embodiments of the disclosure. Methods 600 may be practiced, for example, to fabricate any transistor structure discussed herein. FIGS. 7, 8, 9, 10, 11, 12, 13, 14, 15, 16, 17, and 18 are cross-sectional views of transistor structures having one or more capping layers on one or more corresponding metal chalcogen layers of the transistor structures evolving as methods 600 are practiced, arranged in accordance with some embodiments of the disclosure. Although illustrated with respect to GAA transistor structures, methods 600 may be used to fabricate planar transistor structures.

Methods 600 begin at input operation 601, where a workpiece is received for processing. For example, a substrate such as a wafer substrate workpiece may be received for processing. The substrate may include an optional dielectric layer or etch stop layer, in some embodiments. Processing continues at operation 602, where a multilayer stack is formed. The multilayer stack includes TMD multilayer stacks (i.e., metal chalcogen layers and a capping layer on each of the metal chalcogen layers) interleaved with sacrificial layers. In some embodiments, each of the TMD multilayer stacks includes a base material layer (i.e., hafnium oxide), a TMD layer directly on the base material layer, and a capping layer directly on the TMD layer. In some embodiments, each of the TMD multilayer stacks includes a TMD layer and a capping layer directly on the TMD layer, such that the each TMD multilayer stack is absent the base material layer. An optional hard mask layer may be formed over the interleaved layers. The materials of the multilayer stack may be formed using any suitable technique or techniques such as deposition techniques including atomic layer deposition (ALD), physical vapor deposition (PVD), chemical vapor deposition (CVD), plasma enhanced chemical vapor deposition (PECVD), metal-organic chemical vapor deposition (MOCVD), or others. In some embodiments, the sacrificial layers are formed using CVD and the TMD layers are formed using MOCVD. In some embodiments, the capping layer is formed by sputtering an oxide with carbon incorporated therein. For example, the capping layer may be formed using co-sputter techniques.

FIG. 7 illustrates a cross-sectional side view of a transistor structure 700 including a multilayer stack 710 formed over substrate 101 and optional dielectric layer 105. As shown, multilayer stack 710 includes of a number of TMD multilayer stacks 701 interleaved with a number of sacrificial layers 704. Also as shown, in some embodiments, multilayer stack 710 includes an optional hardmask layer 706. As illustrated below, a GAA transistor, dual gate transistor, or nanoribbon transistor may include a stack of nanoribbons such as metal chalcogen layers that extend from a source structure to a drain structure, with the stack of nanoribbons being formed from TMD multilayer stacks 701. Although illustrated with three TMD multilayer stacks 701 (i.e., a tri-layer 2D ribbon transistor device), transistor structure 700 may include any number of TMD multilayer stacks 701 to fabricate any number of nanoribbons.

In some embodiments, each of TMD multilayer stacks 701 includes material layer 115, metal chalcogen layer 110, and capping layer 120. Material layers 115, metal chalcogen layers 110, and capping layers 120 may have any characteristics discussed herein. Similarly, substrate 101 and optional dielectric layer 105 may have any characteristics discussed herein. In embodiments including material layers 115, material layers 115 may enhance growth of metal chalcogen layer 110. As discussed with respect to FIG. 2, material layers 115 are not deployed in some embodiments. For example, TMD multilayer stacks 701 may include only metal chalcogen layers 110 and capping layers 120, and metal chalcogen layers 110 may be formed directly on sacrificial layers 704 (and dielectric layer 105).

Sacrificial layers 704 may be any material that may be etched or removed selectively with respect to TMD multilayer stacks 701. In some embodiments, sacrificial layers 704 are one of silicon oxide (i.e., sacrificial layers 704 include silicon and oxygen), silicon nitride (i.e., sacrificial layers 704 include silicon and nitrogen), silicon oxynitride titanium oxide (i.e., sacrificial layers 704 include silicon, oxygen, and nitrogen), or aluminum oxide (i.e., sacrificial layers 704 include aluminum and oxygen). Notably advantageous sacrificial layers 704 are silicon nitride. Material layers 115, metal chalcogen layers 110, capping layers 120, sacrificial layers 704, and hardmask layer 706 may be formed using ALD, PVD, CVD, PECVD, MOCVD, or the like.

Returning to FIG. 6, processing continues at operation 603, where the multilayer stack formed at operation 602 is patterned, followed by the patterned multilayer stack being embedded in a dielectric material. The multilayer stack may be patterned using any suitable technique or techniques such as lithography and etch techniques. The patterned multilayer stack may then be embedded in dielectric material. For example, the dielectric material may be formed using any suitable technique or techniques such as bulk deposition of a dielectric such as silicon oxide, silicon nitride, or silicon oxynitride followed by planarization.

FIG. 8 illustrates a cross-sectional side view of a transistor structure 800 similar to transistor structure 700 after patterning multilayer stack 710 to form a patterned multilayer stack 801. In some embodiments, a patterned photoresist layer is formed on hardmask layer 706 and etch techniques are used to form patterned multilayer stack 801. In some embodiments, the pattern of the photoresist layer is first transferred to hardmask layer 706 and then to the remainder of patterned multilayer stack 801. In some embodiments, dielectric layer 105 acts as an etch stop layer. As shown, such patterning may define a number of material stacks 111, each including capping layer 120, metal chalcogen layer 110, and optional material layer 115, which are part of patterned multilayer stack 801. In some embodiments, such processing forms material stacks 311 when material layers 115 are not deployed.

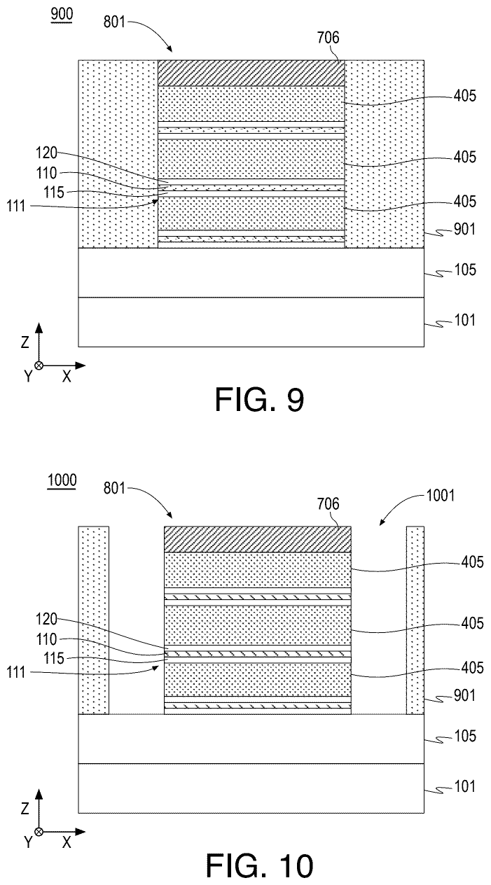

FIG. 9 illustrates a cross-sectional side view of a transistor structure 900 similar to transistor structure 800 after the formation of dielectric material 901. In some embodiments, the photoresist layer is removed and a bulk dielectric material is formed over patterned multilayer stack 801 (with or without hardmask layer 706). Planarization (e.g., chemical mechanical polishing) is then performed to expose patterned multilayer stack 801 and to embed it in dielectric material 401.

Returning to FIG. 6, processing continues at operation 604, where the dielectric material formed at operation 603 is patterned to expose the source and drain ends of the embedded multilayer stack, and a selective recess etch may be performed on the sacrificial layers of the multilayer stack to expose portions of the material layers of interest. The dielectric material may be patterned using any suitable technique or techniques such as photolithography and etch techniques. The recess etch may be performed by selective wet etch or atomic layer etch (ALE) or the like.

FIG. 10 illustrates a cross-sectional side view of a transistor structure 1000 similar to transistor structure 900 after the patterning of dielectric material 901 to form openings 1001 that reveal patterned multilayer stack 801 (and, notably, source and drain ends of metal chalcogen layers 110). In some embodiments, a patterned photoresist layer is formed on the planar top surfaces of patterned multilayer stack 801 and dielectric material 901, and etch techniques are used to form openings 1001.

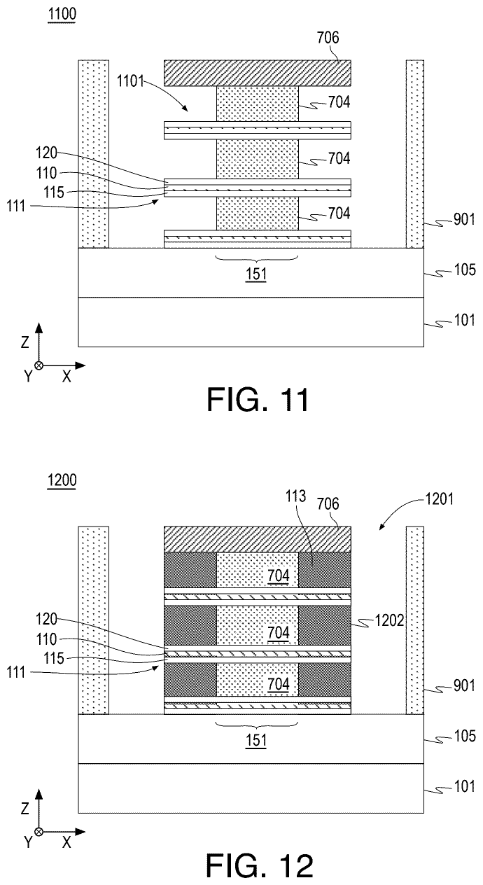

FIG. 11 illustrates a cross-sectional side view of a transistor structure 1100 similar to transistor structure 1000 after a recess etch reveals portions 1101 of material stacks 111, including capping layers 120, metal chalcogen layers 110, and optional material layers 115. The recess etch may include selective wet etch or ALE techniques, for example. Notably, the recess etch may define channel region 151. It is noted that only the ends of metal chalcogen layers 110 need be contacted by source and drain structure for operation of the resultant transistor structure. Furthermore, capping layers 120 and/or material layers 115 may be significantly thin such that some current may flow from source and drain structures through metal chalcogen layers 110. However, in some embodiments, a further recess etch may be performed that selectively removes one or both of capping layers 120 and/or material layers 115 outside of channel region 151 for increased contact area and therefore improved drive current (refer to material 125 of FIG. 1).

Returning to FIG. 6, processing continues at operation 605, where a spacer material is deposited, the spacer material is patterned, and the spacer material is optionally recessed. The spacer material may be formed using any suitable technique or techniques. For example, the spacer material may be bulk deposited followed by planarization. In some embodiments, the spacer material is one of hafnium oxide (i.e., includes hafnium and oxygen), silicon nitride (i.e., includes silicon and nitrogen), silicon oxide (i.e., includes silicon and oxygen), silicon oxynitride (i.e., includes silicon, oxygen, and nitrogen), aluminum oxide (i.e., includes aluminum and oxygen; alumina), titanium oxide (i.e., includes titanium and oxygen), titanium nitride (i.e., includes titanium and nitrogen), tantalum nitride (i.e., includes tantalum and nitrogen), ruthenium, or amorphous hexagonal boron nitride (i.e., includes boron and nitrogen; hBN; white graphene).

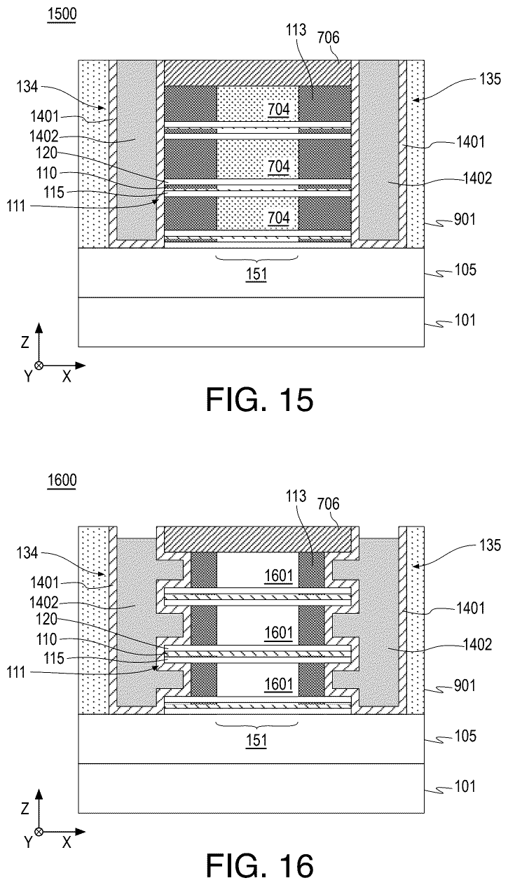

FIG. 12 illustrates a cross-sectional side view of a transistor structure 1200 similar to transistor structure 1100 after formation of spacer material 113. In some embodiments, a bulk spacer material is formed and planarization techniques are used to provide a substantially coplanar top surface. Subsequently, the bulk spacer material may be patterned to form openings 1201 and to form spacer materials 113 having sidewalls 1202 substantially aligned with the outer edges of material stacks 111. In some embodiments, as illustrated herein with respect to FIG. 15, source and drain contact fill may be performed with spacer materials 113 having sidewalls 1202 substantially aligned with the outer edges of material stacks 111. In other embodiments, spacer material 113 may be further recessed. Such techniques may provide for additional surface area contact for source and drain contacts.

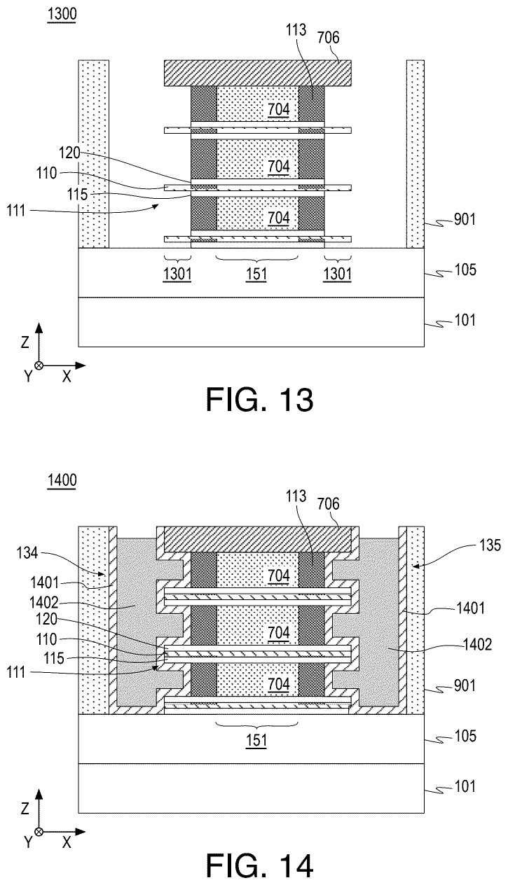

FIG. 13 illustrates a cross-sectional side view of a transistor structure 1300 similar to transistor structure 1200 after an optional recess etch of spacer material 113, followed by an optional recess etch of capping layers 120 and/or material layers 115 to further expose the regions of metal chalcogen layers 110 in source and drain contact regions 1301. The recess etch of spacer material 113 and/or the recess etch of one or both of capping layers 120 and/or material layers 115 may include selective wet etch or ALE techniques, for example. The recess etch of spacer material 113 may increase contact area with source and drain structures, and the resultant structure after only spacer material 113 recess etch is illustrated with respect to FIG. 14.

The additional recess etch to remove one or both of capping layers 120 and/or material layers 115 in source and drain contact regions 1301 may further increase the contact arca between source and drain structures and metal chalcogen layers 110 for reduced resistance, at the cost of increased process complication and at the risk of having reduced protection of metal chalcogen layers 110 in source and drain contact regions 1301. It is noted either of transistor structures 1200, 1300 or a transistor structure with recess etch of spacer material 113 but no etch of capping layers 120 and/or material layers 115 (refer to FIG. 14) may continue with the processing illustrated with respect to a transistor structure having only spacer material 113 recess.

Returning to FIG. 6, processing continues at operation 606, where a source and drain contact metal and subsequent fill metal are formed to provide a source and drain structure. In some embodiments, the source and drain contact metal are applied using ALD or PVD. The source and drain contact metal may include any suitable metal such as those that provide a suitable work function and low contact resistance. In some embodiments, the source and drain contact metal includes one or more of antimony, bismuth, ruthenium, cobalt, copper, tungsten, gold, silver, or palladium. The fill metal or backfill metal may then be formed using any suitable technique or techniques such as electroplating followed by planarization processing. The fill metal may be any suitable conductive metal such as one or more of cobalt, tungsten, copper, or ruthenium. Although discussed with respect to a liner metal and a fill metal, a single metallization may be used in some embodiments, as shown with respect to FIGS. 1 to 3. The single metallization or liner metal and fill metal define a source structure and a drain structure of the transistor.

FIG. 14 illustrates a cross-sectional side view of a transistor structure 1400 similar to transistor structure 1200 after the discussed optional spacer material 113 recess etch, which is followed by deposition of source and drain contact metal 1401, deposition of bulk metal or fill metal 1402, and planarization processing to form source structure 134 and drain structure 135. For example, source structure 134 and drain structure 135 may each include source and drain contact metal 1401 and fill metal 1402, or a single metal contact may be used. For example, source and drain contact metal 1401 may be substantially conformal to exposed surfaces and fill metal 1402 fills the gap of source and drain contact metal 1401. With reference to FIG. 13, source structure 134 and drain structure 135 may be directly on top and bottom surfaces of metal chalcogen layers 110 in source and drain contact regions 1301 when one or both of capping layers 120 and/or material layers 115.

FIG. 15 illustrates a cross-sectional side view of a transistor structure 1500 similar to transistor structure 1200 after the deposition of source and drain contact metal 1401, deposition of bulk metal or fill metal 1402, and planarization processing to form source structure 134 and drain structure 135. As shown, source structure 134 and drain structure 135 may each include source and drain contact metal 1401 and fill metal 1402 such that source and drain contact metal 1401 is conformal to exposed surfaces and fill metal 1402 fills the gap of source and drain contact metal 1401. With reference to FIG. 13, source structure 134 and drain structure 135 may be directly on top and bottom surfaces of metal chalcogen layers 110 in source and drain contact regions 1301. In the embodiment of FIG. 15, metal chalcogen layers 110 are contacted by source structure 134 and drain structure 135 at the sidewall edges or tips of metal chalcogen layers 110.

Discussion now turns to completing fabrication of transistor structures. Such operations may be applied to any transistor structures discussed herein above. Notably, capping layers 120 protect metal chalcogen layers 110 during such processing and other processing to fabricate an IC die including transistor structures.

Returning to FIG. 6, processing continues at operation 607, where remaining portions of the sacrificial layers of the multilayer stack are removed. In some embodiments, a patterned photoresist layer is formed and etch techniques are used to selectively remove the sacrificial layers of the multilayer stack, and the photoresist layer is then removed.

FIG. 16 illustrates a cross-sectional side view of a transistor structure 1600 similar to transistor structure 1400 after the removal of the remaining portions of sacrificial layers 704 to provide gate structure openings 1601. In some embodiments, access to sacrificial layers 704 is provided by patterned openings in dielectric material 901 that are into or out of the page (i.e., in the positive or negative y-dimension) relative to the view shown in FIG. 16. Sacrificial layers 704 are then removed by selective wet etch techniques. As shown, material stacks 111 are free standing but supported by spacer material 113, source structure 134, and drain structure 135.

Returning to FIG. 6, processing continues at operation 608, where gate structures are formed within the openings vacated by the removal of the remaining portions of the sacrificial layers at operation 607. In some embodiments, the gate structure includes a gate dielectric layer and gate electrode. The gate dielectric layer may be formed by conformal deposition using ALD, for example. Similarly, the gate electrode (e.g., gate metal) may be formed using deposition techniques including ALD, plating techniques, or the like. In some embodiments, both the gate dielectric layer and the gate electrode are formed using the access openings formed at operation 607. Such gate dielectric layer and gate electrode deposition may then be followed by planarization techniques.

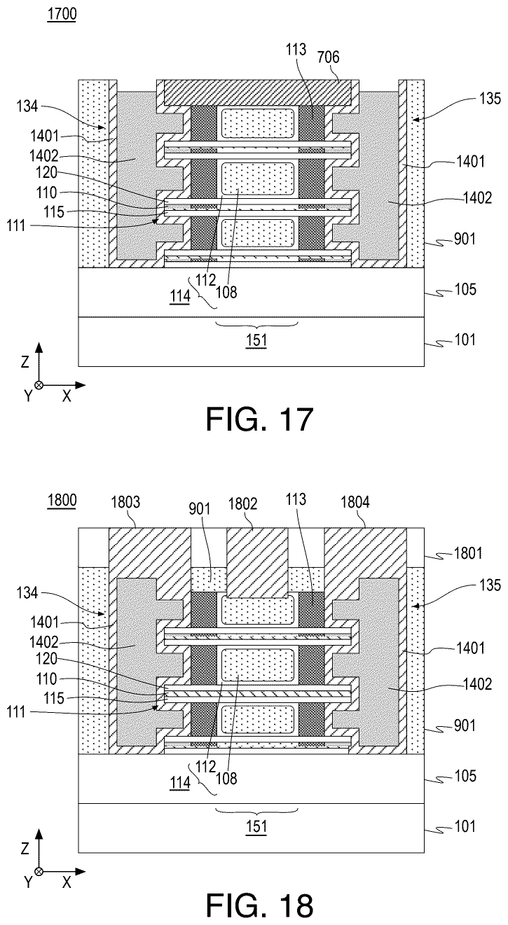

FIG. 17 illustrates a cross-sectional side view of a transistor structure 1700 similar to transistor structure 1600 after the formation of gate structure 114, which includes gate dielectric 112 and gate electrode 108 such that gate electrode 108 is separated from material stacks 111 by gate dielectric 112. Gate dielectric 112 may have a high relative permittivity (i.e., dielectric constant, K). In some high-K gate dielectric embodiments, gate dielectric 112 is a metal oxide including oxygen and one or more metals, such as, but not limited to, aluminum, hafnium, zirconium, tantalum, or titanium. In some embodiments, gate dielectric 112 is silicon oxide. Gate electrode 108 may be or include a metal such as but not limited to platinum, nickel, molybdenum, tungsten, palladium, gold, alloys thereof, or nitrides such as titanium nitride, tantalum nitride, tungsten silicon nitride, or others. In some embodiments, gate electrode 108 includes a work function metal and a fill metal. After deposition of gate dielectric 112 and gate electrode 108, a planarization process is performed to remove the gate dielectric layer and the gate electrode layer from an uppermost surface of transistor structure 1700.

Returning to FIG. 6, processing continues at operation 609, where gate, source, and drain contacts are formed. In some embodiments, after gate formation, an overlying dielectric layer is deposited, and source and drain contact openings are formed in the dielectric layer using lithography and etch techniques. The openings are then filled with a contact metal or metal(s), followed by planarization processing.

FIG. 18 illustrates a cross-sectional side view of a transistor structure 1800 similar to transistor structure 1700 after the formation of gate contact 1802, source contact 1803, drain contact 1804, and dielectric material 1801. In some embodiments, a bulk dielectric layer is formed over a top surface of transistor structure 1800 and a resist layer is deposited and patterned on the bulk dielectric layer. Etch techniques are then used to form openings corresponding to gate contact 1802, source contact 1803, drain contact 1804, and the resist layer is removed. The openings are then filled with contact metal and planarization techniques are used to form a planar top surface of transistor structure 1800. In some embodiments, the metal of gate contact 1802, source contact 1803, drain contact 1804 are the same as that of source and drain contact metal 1401 (as shown) or fill metal 1402, however, other metals may be used. Dielectric material 1801 may include any suitable insulative material such as silicon oxide, silicon nitride, silicon oxynitride, or the like.

Returning to FIG. 6, processing continues at operation 610, where continued processing is performed as is known in the art. Such processing may include forming interconnect features including metallization routings and vias, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

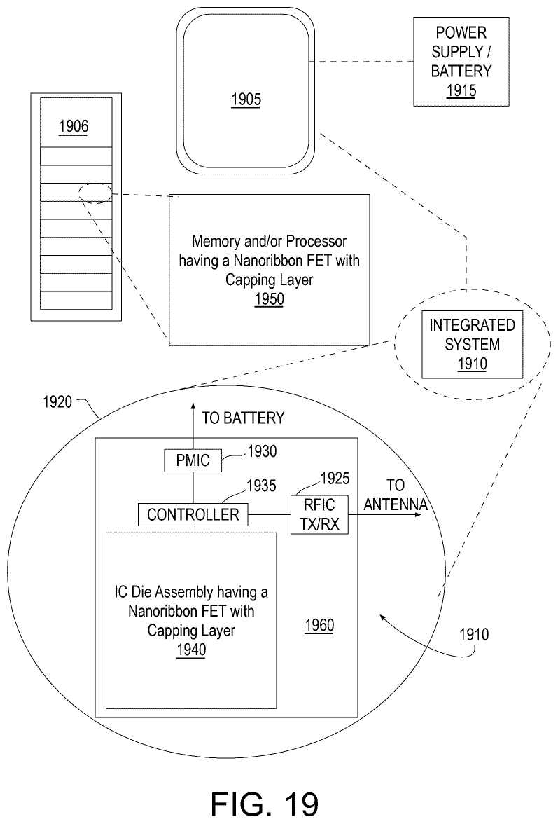

FIG. 19 illustrates exemplary systems employing metal chalcogen material-based transistor structures having a capping layer on the metal chalcogen nanoribbons, in accordance with some embodiments. The system may be a mobile computing platform 1905 and/or a data server machine 1906, for example. Either may employ a monolithic IC die, for example, having a field effect transistor with one or more metal chalcogen layers (e.g., nanoribbons) having a capping layer on each of the nanoribbons as described elsewhere herein. Server machine 1906 may be any commercial server, for example including any number of high-performance computing platforms disposed within a rack and networked together for electronic data processing, which in the exemplary embodiment includes an IC die assembly 1950 with a field effect transistor having a field effect transistor with one or more metal chalcogen layers (e.g., nanoribbons) having a capping layer on each of the nanoribbons as described elsewhere herein. Mobile computing platform 1905 may be any portable device configured for each of electronic data display, electronic data processing, wireless electronic data transmission, or the like. For example, mobile computing platform 1905 may be any of a tablet, a smart phone, a laptop computer, etc., and may include a display screen (e.g., a capacitive, inductive, resistive, or optical touchscreen), a chip-level or package-level integrated system 1910, and a battery/power supply 1915. Although illustrated with respect to mobile computing platform 1905, in other examples, chip-level or package-level integrated system 1910 and a battery/power supply 1915 may be implemented in a desktop computing platform, an automotive computing platform, an internet of things platform, or the like. As discussed below, in some examples, the disclosed systems may include a sub-system 1960 such as a system on a chip (SOC) or an integrated system of multiple ICs, which is illustrated with respect to mobile computing platform 1905.

Whether disposed within integrated system 1910 illustrated in expanded view 1920 or as a stand-alone packaged device within data server machine 1906, sub-system 1960 may include memory circuitry and/or processor circuitry 1940 (e.g., RAM, a microprocessor, a multi-core microprocessor, graphics processor, etc.), a power management integrated circuit (PMIC) 1930, a controller 1935, and a radio frequency integrated circuit (RFIC) 1925 (e.g., including a wideband RF transmitter and/or receiver (TX/RX)). As shown, one or more IC dice, such as memory circuitry and/or processor circuitry 1940 may be assembled and implemented such that one or more have a field effect transistor with one or more metal chalcogen layers (e.g., nanoribbons) having a capping layer on each of the nanoribbons as described herein. In some embodiments, RFIC 1925 includes a digital baseband and an analog front end module further comprising a power amplifier on a transmit path and a low noise amplifier on a receive path). Functionally, PMIC 1930 may perform battery power regulation, DC-to-DC conversion, etc., and so has an input coupled to battery/power supply 1915, and an output providing a current supply to other functional modules. As further illustrated in FIG. 19, in the exemplary embodiment, RFIC 1925 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1940 may provide memory functionality for sub-system 1960, high level control, data processing and the like for sub-system 1960. In alternative implementations, each of the SOC modules may be integrated onto separate ICs coupled to a package substrate, interposer, or board. For example, any transistor structure discussed herein may be deployed as part of an IC die that is a component of the systems of FIG. 19.

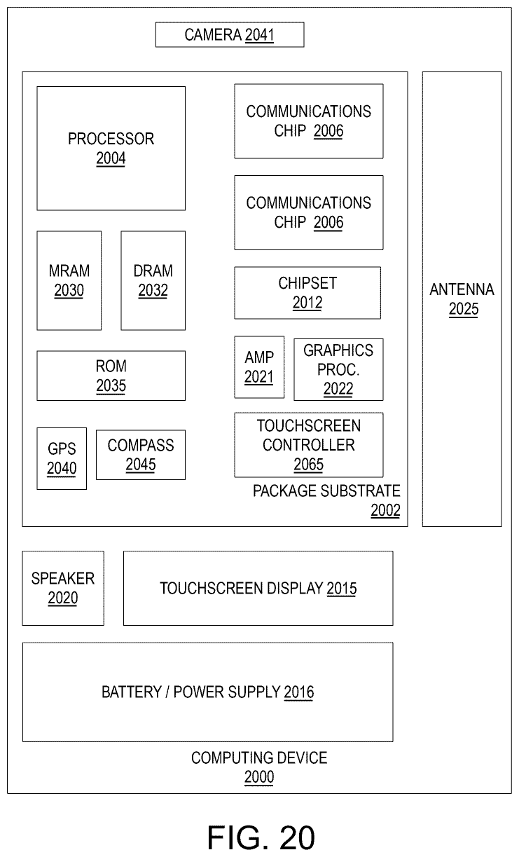

FIG. 20 is a functional block diagram of an electronic computing device 2000, in accordance with some embodiments. For example, device 2000 may, via any suitable component therein, implement a field effect transistor having a field effect transistor with one or more metal chalcogen layers (e.g., nanoribbons) having a capping layer on each of the nanoribbons as discussed herein. For example, one or more IC dies of electronic computing device 2000 may deploy a GAA transistor having a field effect transistor with one or more metal chalcogen layers (e.g., nanoribbons) having a capping layer on each of the nanoribbons. Device 2000 further includes a motherboard or package substrate 2002 hosting a number of components, such as, but not limited to, a processor 2004 (e.g., an applications processor). Processor 2004 may be physically and/or electrically coupled to package substrate 2002. In some examples, processor 2004 is within an IC assembly. In general, the term “processor” or “microprocessor” may refer to any device or portion of a device that processes electronic data from registers and/or memory to transform that electronic data into other electronic data that may be further stored in registers and/or memory.

In various examples, one or more communication chips 2006 may also be physically and/or electrically coupled to the package substrate 2002. In further implementations, communication chips 2006 may be part of processor 2004. Depending on its applications, computing device 2000 may include other components that may or may not be physically and electrically coupled to package substrate 2002. These other components include, but are not limited to, volatile memory (e.g., DRAM 2032), non-volatile memory (e.g., ROM 2035), flash memory (e.g., NAND or NOR), magnetic memory (MRAM 2030), a graphics processor 2022, a digital signal processor, a crypto processor, a chipset 2012, an antenna 2025, touchscreen display 2015, touchscreen controller 2065, battery/power supply 2016, audio codec, video codec, power amplifier 2021, global positioning system (GPS) device 2040, compass 2045, accelerometer, gyroscope, speaker 2020, camera 2041, and mass storage device (such as hard disk drive, solid-state drive (SSD), compact disk (CD), digital versatile disk (DVD), and so forth, or the like.

Communication chips 2006 may enable wireless communications for the transfer of data to and from the computing device 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 2006 may implement any of a number of wireless standards or protocols, including, but not limited to, those described elsewhere herein. As discussed, computing device 2000 may include a plurality of communication chips 2006. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. Battery/power supply 2016 may include any suitable power supply circuitry and, optionally, a battery source to provide power to components of electronic computing device 2000.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a source structure and a drain structure, a first material layer coupled to each of the source structure and the drain structure, the first material layer comprising a transition metal and a chalcogen, a second material layer directly on the first material layer, the second material layer comprising oxygen, carbon, and a metal or metalloid element, and a gate structure adjacent to a channel region of the first material layer, the gate structure comprising a gate metal separated from the channel region by a gate dielectric material.

In one or more second embodiments, further to the first embodiments, the gate dielectric material is directly on the second material layer.

In one or more third embodiments, further to the first or second embodiments, the metal or metalloid comprises one of hafnium, silicon, zirconium, yttrium, aluminum, tantalum, niobium, or titanium.

In one or more fourth embodiments, further to the first through third embodiments, the first material layer is one of a plurality of first material layers each extending between and coupled to each of the source structure and the drain structure, and each comprising the transition metal or a second transition metal and the chalcogen or a second chalcogen, such that the second material layer is one of a plurality of second material layers each directly on a respective one of the first material layers, and each comprising oxygen, carbon and the metal or metalloid element or a second metal or metalloid element.

In one or more fifth embodiments, further to the first through fourth embodiments, the apparatus further comprises a plurality of third material layers each directly on a respective one of the first material layers and opposite the respective one of the first material layers from the second material layer, each of the third material layers comprising oxygen and hafnium.

In one or more sixth embodiments, further to the first through fifth embodiments, each of the first material layers comprise the transition metal and the chalcogen, the transition metal is tungsten or molybdenum, and the chalcogen is selenium or sulfur.

In one or more seventh embodiments, further to the first through sixth embodiments, the gate dielectric material is directly on the first material layer and opposite the first material layer from the second material layer.

In one or more eighth embodiments, further to the first through seventh embodiments, the second material layer comprises a crystalline or nanocrystalline compound of oxygen, carbon, and the metal or metalloid element.

In one or more ninth embodiments, further to the first through eighth embodiments, the second material layer comprises a multilayer stack comprising a carbon layer directly on the first material layer and a compound of oxygen and the metal or metalloid element directly on the carbon layer.

In one or more tenth embodiments, further to the first through ninth embodiments, the second material layer comprises not less than 5% carbon.

In one or more eleventh embodiments, further to the first through tenth embodiments, the apparatus further comprises an integrated circuit (IC) die comprising a transistor comprising source structure, the drain structure, the first material layer, the second material layer, the gate structure, and a power supply coupled to the IC die.

In one or more twelfth embodiments, an apparatus comprises a source structure and a drain structure, a nanoribbon coupled to each of the source structure and the drain structure, the nanoribbon comprising a transition metal and a chalcogen, a first material layer directly on a bottom side of the nanoribbon, the first material layer comprising a compound of hafnium and oxygen, a second material layer directly on a top side of the nanoribbon, the second material layer comprising a compound of a metal or metalloid element and oxygen, and a gate structure adjacent to a channel region of the nanoribbon, the gate structure comprising a gate dielectric material directly on the first material layer and the second material layer and a gate metal directly on the gate dielectric material.

In one or more thirteenth embodiments, further to the twelfth embodiments, the metal or metalloid comprises one of hafnium, silicon, zirconium, yttrium, aluminum, tantalum, niobium, or titanium.

In one or more fourteenth embodiments, further to the twelfth or thirteenth embodiments, the second material layer further comprises not less than 1% carbon.

In one or more fifteenth embodiments, further to the twelfth through fourteenth embodiments, the nanoribbon is one of a plurality of nanoribbons each extending between and coupled to each of the source structure and the drain structure, and each comprising the transition metal and the chalcogen, such that the first material layer is one of a plurality of first material layers each directly on a bottom side of a respective one of the nanoribbons, and each comprising the compound of hafnium and oxygen, and such that the second material layer is one of a plurality of second material layers each directly on a top side of a respective one of the nanoribbons, and each comprising the compound of the metal or metalloid element and oxygen.

In one or more sixteenth embodiments, further to the twelfth through fifteenth embodiments, the apparatus further comprises an integrated circuit (IC) die comprising a transistor comprising source structure, the drain structure, the first material layer, the second material layer, the gate structure, and a power supply coupled to the IC die.

In one or more seventeenth embodiments, an apparatus comprises a source structure and a drain structure, a first material layer coupled to each of the source structure and the drain structure, the first material layer comprising a transition metal and a chalcogen, the transition metal comprising tungsten or molybdenum and the chalcogen comprising selenium or sulfur, a second material layer directly on the first material layer, the second material layer comprising a compound of oxygen and aluminum, and a gate structure adjacent to a channel region of the first material layer, the gate structure comprising gate dielectric material directly on the first material layer or the second material layer and a gate metal directly on the gate dielectric material.

In one or more eighteenth embodiments, further to the seventeenth embodiments, the compound of oxygen and aluminum further comprises not less than 1% carbon.

In one or more nineteenth embodiments, further to the seventeenth or eighteenth embodiments, the first material layer is one of a plurality of first material layers each extending between and coupled to each of the source structure and the drain structure, and each comprising the transition metal and the chalcogen, such that the second material layer is one of a plurality of second material layers each directly on a respective one of the first material layers, and each comprising the compound of oxygen and aluminum.

In one or more twentieth embodiments, further to the seventeenth through nineteenth embodiments, the apparatus further comprises an integrated circuit (IC) die comprising a transistor comprising source structure, the drain structure, the first material layer, the second material layer, the gate structure, and a power supply coupled to the IC die.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a source structure and a drain structure;
a first material layer coupled to each of the source structure and the drain structure, the first material layer comprising a transition metal and a chalcogen;
a second material layer directly on the first material layer, the second material layer comprising oxygen, carbon, and a metal or metalloid element; and
a gate structure adjacent to a channel region of the first material layer, the gate structure comprising a gate metal separated from the channel region by a gate dielectric material.

2. The apparatus of claim 1, wherein the gate dielectric material is directly on the second material layer.

3. The apparatus of claim 1, wherein the metal or metalloid comprises one of hafnium, silicon, zirconium, yttrium, aluminum, tantalum, niobium, or titanium.

4. The apparatus of claim 1, wherein the first material layer is one of a plurality of first material layers each extending between and coupled to each of the source structure and the drain structure, and each comprising the transition metal or a second transition metal and the chalcogen or a second chalcogen, and wherein the second material layer is one of a plurality of second material layers each directly on a respective one of the first material layers, and each comprising oxygen, carbon and the metal or metalloid element or a second metal or metalloid element.

5. The apparatus of claim 4, further comprising:
a plurality of third material layers each directly on a respective one of the first material layers and opposite the respective one of the first material layers from the second material layer, each of the third material layers comprising oxygen and hafnium.

6. The apparatus of claim 5, wherein each of the first material layers comprise the transition metal and the chalcogen, the transition metal is tungsten or molybdenum, and the chalcogen is selenium or sulfur.

7. The apparatus of claim 1, wherein the gate dielectric material is directly on the first material layer and opposite the first material layer from the second material layer.

8. The apparatus of claim 1, wherein the second material layer comprises a crystalline or nanocrystalline compound of oxygen, carbon, and the metal or metalloid element.

9. The apparatus of claim 1, wherein the second material layer comprises a multilayer stack comprising a carbon layer directly on the first material layer and a compound of oxygen and the metal or metalloid element directly on the carbon layer.

10. The apparatus of claim 1, wherein the second material layer comprises not less than 5% carbon.

11. The apparatus of claim 1, further comprising:
an integrated circuit (IC) die comprising a transistor comprising source structure, the drain structure, the first material layer, the second material layer, the gate structure; and
a power supply coupled to the IC die.

12. An apparatus, comprising:
a source structure and a drain structure;
a nanoribbon coupled to each of the source structure and the drain structure, the nanoribbon comprising a transition metal and a chalcogen;
a first material layer directly on a bottom side of the nanoribbon, the first material layer comprising a compound of hafnium and oxygen;
a second material layer directly on a top side of the nanoribbon, the second material layer comprising a compound of a metal or metalloid element and oxygen; and
a gate structure adjacent to a channel region of the nanoribbon, the gate structure comprising a gate dielectric material directly on the first material layer and the second material layer and a gate metal directly on the gate dielectric material.

13. The apparatus of claim 12, wherein the metal or metalloid comprises one of hafnium, silicon, zirconium, yttrium, aluminum, tantalum, niobium, or titanium.

14. The apparatus of claim 12, wherein the second material layer further comprises not less than 1% carbon.

15. The apparatus of claim 12, wherein the nanoribbon is one of a plurality of nanoribbons each extending between and coupled to each of the source structure and the drain structure, and each comprising the transition metal and the chalcogen, wherein the first material layer is one of a plurality of first material layers each directly on a bottom side of a respective one of the nanoribbons, and each comprising the compound of hafnium and oxygen, and wherein the second material layer is one of a plurality of second material layers each directly on a top side of a respective one of the nanoribbons, and each comprising the compound of the metal or metalloid element and oxygen.

16. The apparatus of claim 12, further comprising:
an integrated circuit (IC) die comprising a transistor comprising source structure, the drain structure, the first material layer, the second material layer, the gate structure; and
a power supply coupled to the IC die.

17. An apparatus, comprising:
a source structure and a drain structure;
a first material layer coupled to each of the source structure and the drain structure, the first material layer comprising a transition metal and a chalcogen, the transition metal comprising tungsten or molybdenum and the chalcogen comprising selenium or sulfur;
a second material layer directly on the first material layer, the second material layer comprising a compound of oxygen and aluminum; and
a gate structure adjacent to a channel region of the first material layer, the gate structure comprising gate dielectric material directly on the first material layer or the second material layer and a gate metal directly on the gate dielectric material.

18. The apparatus of claim 17, wherein the compound of oxygen and aluminum further comprises not less than 1% carbon.

19. The apparatus of claim 18, wherein the first material layer is one of a plurality of first material layers each extending between and coupled to each of the source structure and the drain structure, and each comprising the transition metal and the chalcogen, and wherein the second material layer is one of a plurality of second material layers each directly on a respective one of the first material layers, and each comprising the compound of oxygen and aluminum.

20. The apparatus of claim 17, further comprising:
an integrated circuit (IC) die comprising a transistor comprising source structure, the drain structure, the first material layer, the second material layer, the gate structure; and
a power supply coupled to the IC die.
